(19) United States
(12) Patent Application Publication
(10) Pub. No.: US 2026/0144143 A1
(43) Pub. Date: May 21, 2026

(54) Power Semiconductor Device Package

(71) Applicant: Wolfspeed, Inc., Durham, NC (US)

(72) Inventors: Devarajan Balaraman, Apex, NC (US); Urvi Ahluwalia, Durham, NC (US)

(21) Appl. No.: 18/952,571

(22) Filed: Nov. 19, 2024

(51) Int. Cl. H01L 25/18; H01L 23/00; H01L 23/13; H01L 23/31; H01L 23/498

(52) U.S. Cl. CPC H10W 90/00; H10W 70/658; H10W 70/68; H10W 74/111; H10W 72/884; H10W 72/886; H10W 90/734; H10W 90/754; H10W 90/764

(57) ABSTRACT

Power semiconductor packages are provided. In one example, the power semiconductor package includes a first semiconductor die, a second semiconductor die, and a submount having a first side and a second side opposing the first side. The first semiconductor die is coupled to the first side of the submount, and the second semiconductor die is coupled to the second side of the submount.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor package. The power semiconductor package includes a first semiconductor die, a second semiconductor die, and a submount having a first side and a second side opposing the first side. The first semiconductor die is coupled to the first side of the submount, and the second semiconductor die is coupled to the second side of the submount.

Another example aspect of the present disclosure is directed to a power semiconductor package. The power semiconductor package includes a first semiconductor die. The first semiconductor die includes a MOSFET. The power semiconductor package further includes a second semiconductor die. The second semiconductor die includes a Schottky diode. The power semiconductor package further includes a submount having a first side and a second side opposing the first side. The first semiconductor die is coupled to the first side of the submount, and the second semiconductor die is coupled to the second side of the submount.

Another example aspect of the present disclosure is directed to a power semiconductor package. The power semiconductor package includes a first semiconductor die, a second semiconductor die, a first electrical connector coupled to the first semiconductor die and a first terminal of the power semiconductor package, a second electrical connector coupled to the second semiconductor die and a second terminal of the power semiconductor package, and a housing. At least a portion of the first electrical connector between the first semiconductor die and the first terminal is exposed through a first side of the housing, and at least a portion of the second electrical connector between the second semiconductor die and the second terminal is exposed through a second side of the housing. The first side of the housing is opposite the second side of the housing.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIGS. 1A and 1B depict an example semiconductor device package according to example embodiments of the present disclosure;

FIG. 2 depicts a top view of a first semiconductor die mounted to a submount according to example embodiments of the present disclosure;

FIG. 3 depicts a top view of a second semiconductor die mounted to a submount according to example embodiments of the present disclosure;

FIG. 4 depicts a cross-sectional view of a first semiconductor die and a second semiconductor die mounted to a submount according to example embodiments of the present disclosure;

FIGS. 5A and 5B depicts an example power circuit implemented a power semiconductor device package according to example embodiments of the present disclosure;

FIG. 6 depicts a cross-sectional view of a first semiconductor die and a second semiconductor die mounted to a submount according to example embodiments of the present disclosure;

FIG. 7 depicts a cross-sectional view of a first semiconductor die and a second semiconductor die mounted to a submount according to example embodiments of the present disclosure;

FIG. 8 depicts a top view of a first semiconductor die mounted to a submount according to example embodiments of the present disclosure;

FIG. 9 depicts a top view of a second semiconductor die mounted to a submount according to example embodiments of the present disclosure;

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages, such as power semiconductor device packages (e.g., discrete power semiconductor device packages, power modules, etc.), have been developed that include a semiconductor die. In some examples, such semiconductor die include one or more semiconductor devices, such as a metal-oxide-semiconductor field-effect transistor (MOSFET), a Schottky diode, and/or a high electron mobility transistor (HEMT) device. Power semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems.

Example aspects of the present disclosure are directed to power semiconductor device packages (e.g., discrete power semiconductor device packages, power modules, etc.) for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide (SiC) and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a metal-oxide-semiconductor field-effect transistor (MOSFET), such as a silicon carbide-based MOSFET. In such examples, the MOSFET(s) may be located between a first (e.g., source) lead and a second (e.g., drain) lead of a power semiconductor device package to form, for instance, a vertical structure power semiconductor device. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices and silicon carbide-based Schottky diode devices for purposes of illustration and discussion. Those having ordinary skill in the art, using the disclosures provided herein, will understand that the power semiconductor device packages of the present disclosure may include other power semiconductor devices without deviating from the scope of the present disclosure, such as, by way of non-limiting example, diodes (e.g., PiN diodes, etc.), insulated gate bipolar transistors, HEMTs, and/or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal structure power semiconductor devices and/or the like.

In some power semiconductor device packages, the one or more semiconductor die may be attached to a submount, such as a lead frame and/or a power substrate (e.g., direct bonded copper (DBC) substrate, active metal brazed (AMB) substrate, etc.), for instance, by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum wire bond(s)) or other electrical connectors, such as clips, ribbon bond(s), etc., for connection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC)) formed around at least a portion of the submount, and the one or more semiconductor die.

The power semiconductor device package may also include one or more electrical leads or terminals extending from the housing. The terms “terminals” and “leads” may be used in the present disclosure interchangeably. In some examples, the power semiconductor device package may include a plurality of electrical terminals, each of which extend from a same side of the housing relative to one another. In other examples, the power semiconductor device package may include a plurality of electrical terminals, at least one of which extending from a different side of the housing relative to the other electrical terminals. It should be understood that, as used herein, a “plurality of electrical terminals” includes at least two, or more, electrical leads extending from the housing.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Packaging technology for semiconductor devices plays an important role in defining the performance of the semiconductor devices. For example, the packaging of a power semiconductor device package may limit the ability of the one or more semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

The packaging of a power semiconductor die may also affect clearance and creepage of the semiconductor device. More particularly, clearance (or “clearance distance”) is the shortest direct path through air between conductors at different voltage potentials. Adequate clearance distances are vital to preventing an ionization of an air gap of the semiconductor device because a breakdown along a clearance path can happen instantaneously under certain operating conditions.

Similarly, creepage (or “creepage distance”) is the shortest direct path along a surface between conductors at different voltage potentials. As such, the packaging of the power semiconductor device plays an important role in determining the creepage distance of the power semiconductor device. Creepage may occur in situations where charge carriers are influenced by, for instance, electric fields, temperature gradients, and/or other factors that cause the charge carriers to drift along the surface of the power semiconductor device. Depending on the packaging and operating conditions of the power semiconductor device, creepage may contribute to leakage currents and/or other non-ideal behaviors in the semiconductor device. Thus, creepage distances are an important design consideration to ensure proper insulation and to prevent electrical breakdown, especially in high-voltage applications that require increased creepage distances.

Semiconductor device packages implementing power circuits, such as half bridge modules may be large and bulky. The large size of such semiconductor device packages may be a drawback for certain applications, such as for automotive applications. Aspects of the present disclosure provide a way to create compact packages that may be used to implement power circuits (e.g., half-bridge circuits) and may allow for implementation of power circuits in discrete semiconductor device packages.

More particularly, according to examples of the present disclosure, one or more semiconductor die may be on either or both sides of a submount, such as a lead frame or power substrate, in a power semiconductor device package. The one or more semiconductor die may be mounted to the submount using a die-attach material to provide an electrical and/or thermal connection for the one or more semiconductor die to either or both sides of the submount. The one or more semiconductor die may be coupled to leads or terminals for the semiconductor device package using a suitable electrical connector, such as a clip, wire bond, ribbon bond, or other suitable electrical connector.

In some examples, electrical connectors (e.g., clips, wire bonds, ribbon bonds, etc.) may be exposed through opposite sides of the housing of the semiconductor device package. In this way, the electrical connectors may be used to provide efficient thermal dissipation and/or a dual sided cooling configuration.

In some examples, a MOSFET semiconductor die and a Schottky diode semiconductor die may be implemented on opposite sides of a submount in a semiconductor device package, for instance, to implement a power circuit, such as a half-bridge power circuit. Other suitable power circuits may be implemented in a semiconductor device package without deviating from the scope of the present disclosure.

In some power semiconductor device packages according to examples of the present disclosure, a first semiconductor die may be on a submount. A second semiconductor die may be on the submount. The first semiconductor die and the second semiconductor die may be on opposing sides of the submount.

In some examples, the first semiconductor die may be a MOSFET. In some embodiments, the MOSFET may include a drain contact (e.g., a drain), a gate contact and a source contact. In some embodiments the drain contact may be on the submount (e.g., coupled to the submount via, for instance, a die-attach material).

The power semiconductor package may include a plurality of terminals. The plurality of terminals may include a first terminal, a second terminal, a third terminal and a fourth terminal. The first terminal may be coupled to the submount. The second terminal may be coupled to the source contact of the MOSFET. The third terminal may be coupled to the gate contact of the MOSFET. The source contact of the MOSFET may be coupled to the second terminal with an electrical connector. The electrical connector may be exposed, either in a portion or as a whole, through a housing of the power semiconductor package. The electrical connector may be a clip, a wire bond, a ribbon bond, etc.

In some examples, the second semiconductor die may be a Schottky diode. The Schottky diode may have an anode contact and a cathode contact. The anode contact may be on the submount (e.g., coupled to the submount via, for instance, a die-attach material). In this way, the submount may act as a common node for the MOSFET and the Schottky diode (e.g., to implement a power circuit, such as a half-bridge module).

The cathode contact may be coupled to a terminal, for instance, with an electrical connector. The electrical connector may be exposed, either in a portion or as a whole, through a housing of the power semiconductor package. The electrical connector may be a clip, a wire bond, ribbon bond, etc. As discussed above, the power semiconductor package may comprise a plurality of including a first terminal, a second terminal, a third terminal and a fourth terminal. The anode contact may be coupled with the first terminal of the power semiconductor package. The cathode contact may be coupled with the third terminal of the power semiconductor package (e.g., by an electrical connector).

In some embodiments, the first semiconductor die and the second semiconductor die may be thermally coupled and/or electrically coupled via the submount. In some embodiments, the first semiconductor die and the second semiconductor die may be electrically coupled and thermally isolated via the submount. In some embodiments, the first semiconductor die and the second semiconductor die may be electrically isolated and thermally coupled via the submount. In some embodiments, the first semiconductor die, and the second semiconductor die may be electrically isolated and thermally isolated.

Aspects of the present disclosure provide a number of technical effects and benefits. For instance, aspects of the present disclosure may provide for compact packaging (e.g., in discrete power semiconductor packages) of complex power circuits, such as half-bridge modules. In some examples, aspects of the present disclosure may provide for efficient electrical and/or thermal coupling of different semiconductor die on opposite sides of a submount. In some examples, aspects of the present disclosure may provide for dual side cooling through electrical connectors exposed through opposite sides of a housing of the semiconductor device package.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

Aspects of the present disclosure are discussed with reference to silicon carbide-based semiconductor structures such as MOSFETs and Schottky diodes. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

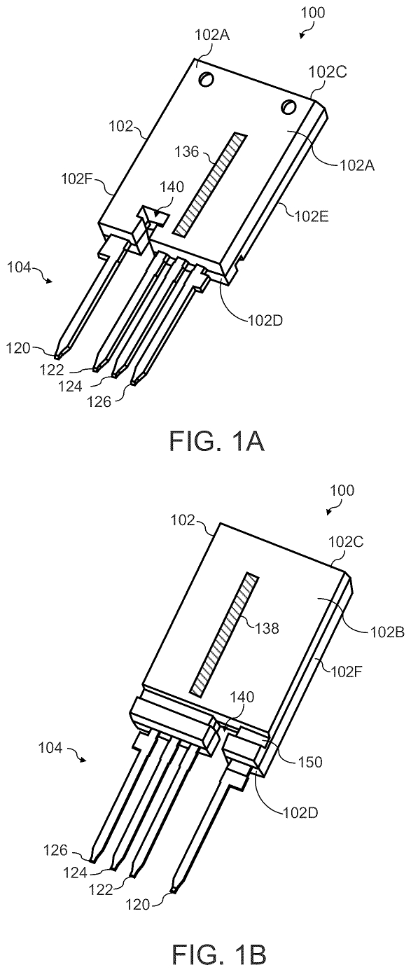

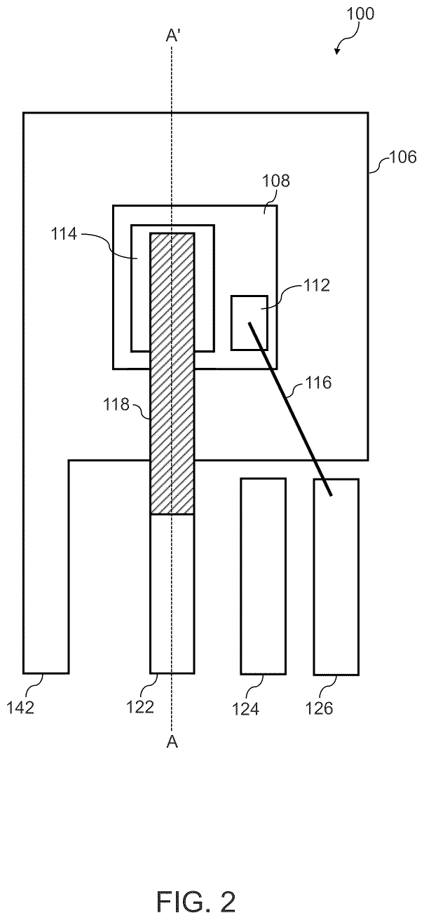

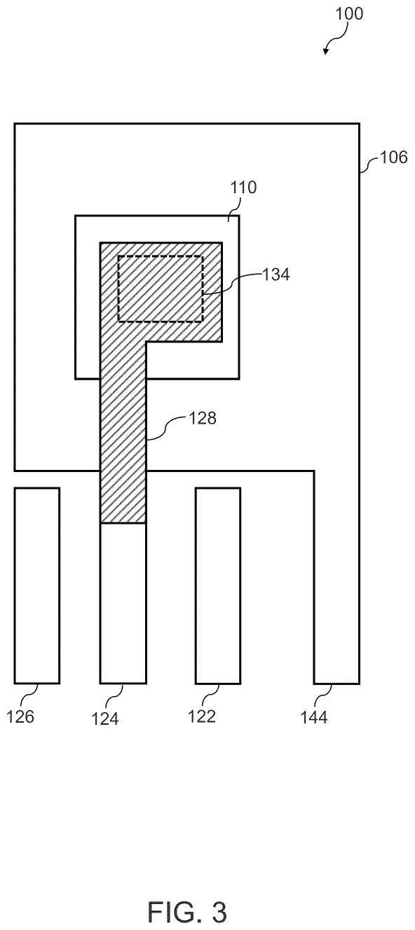

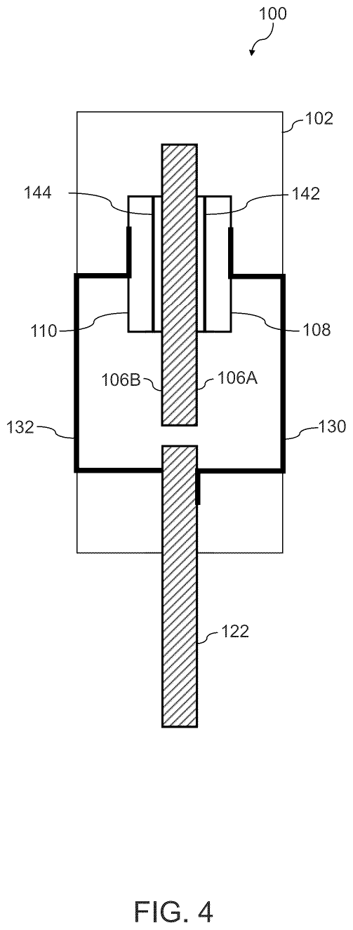

FIGS. 1-4 depict a power semiconductor device package 100. FIG. 1A depicts a top view of the power semiconductor device package 100. FIG. 1B depicts a bottom view of the power semiconductor device package 100. FIG. 2 depicts a plan view of internal components of the power semiconductor device package 100. FIG. 3 depicts a plan view of internal components of the power semiconductor device package 100. FIG. 4 depicts a cross-sectional view of internal components of the power semiconductor device package 100 along line A-A′.

The power semiconductor device package 100 includes a housing 102. The housing 102 may be formed by a mold press. The housing 102 may include a material capable of high temperature operation, such as a temperature of about 200° C. or greater. In some examples, the housing 102 may be and/or may include an encapsulating material. By way of non-limiting example, the housing 102 may be and/or may include an epoxy material, an epoxy mold compound, and/or the like.

The housing 102 may include one or more surfaces and/or one or more sides. For instance, the housing may include one or more “major” sides and one or more “minor” sides. As noted above, a “major side(s)” and/or a “major surface(s)” refers to a primary (e.g., most significant) surface(s) of the housing 102, such as the principal face(s) of the housing 102, the side(s) having the largest surface area, and/or the like. Conversely, a “minor side(s)” and/or a “minor surface(s)” refers to a secondary (e.g., less prominent) surface(s) of the housing 102 relative to the “major side(s),” such as the side surface(s) of the housing 102, the side(s) having a smaller surface area relative to the principal faces, and/or the like. It should be understood that, when describing the housing 102, the terms “surface” and “side” may be used interchangeably.

For instance, the housing 102 may include a first major side 102A (e.g., top side) (FIG. 1A) and a second major side 102B (e.g., bottom side) (FIG. 1B). The second major side 102B may be generally opposite the first major side 102A. The first major side 102A and the second major side 102B may be generally parallel relative to one another. The first major side 102A and the second major side 102B may be the principal faces of the housing 102.

The housing 102 may further include one or more minor sides extending between the first major side 102A and the second major side 102B. For instance, the housing 102 may include a first minor side 102C (e.g., back-side surface) and a second minor side 102D (e.g., front-side surface). The second minor side 102D may be generally opposite the first minor side 102C. The first minor side 102C and the second minor side 102D may be generally perpendicular to the first major side 102A and the second major side 102B. The first minor side 102C and the second minor side 102D may be generally parallel relative to one another. The housing 102 may further include a third minor side 102E (e.g., right-side surface) and a fourth minor side 102F (e.g., left-side surface). The fourth minor side 102F (e.g., defining a first peripheral end of the housing 102) may be generally opposite the third minor side 102E (e.g., defining a second peripheral end of the housing 102). The third minor side 102E and the fourth minor side 102F may be generally perpendicular to the first major side 102A and the second major side 102B; likewise, the third minor side 102E and the fourth minor side 102F may be perpendicular to the first minor side 102C and the second minor side 102D. The third minor side 102E and the fourth minor side 102F may be generally parallel relative to one another.

It should be understood that the housing 102 may include different arrangements of surfaces without deviating from the scope of the present disclosure. For instance, one or more notches and/or one or more recesses may be formed on any of the sides and/or surfaces of the housing 102 without deviating from the scope of the present disclosure.

In some examples, the power semiconductor device package 100 may further include a creepage extension structure 150 (e.g., creepage trench, creepage step structure) in the housing 102. The creepage extension structure 150 may have any suitable shape and/or configuration. By way of non-limiting example, the creepage extension structure 150 may be a rectangular creepage extension structure and/or a non-rectangular creepage extension structure. For instance, in some examples, the creepage extension structure 150 may be a trench structure or a step structure.

In some examples, the power semiconductor device package 100 may include a creepage cutout 140. In the example of FIGS. 1-4, the power semiconductor device package 100 includes a creepage cutout 140 in the housing 102 between the first terminal 120 of the plurality of terminals 104 and the second, third and fourth terminals 122, 124, 126 of the plurality of terminals 104. In such examples, the creepage cutout 140 may provide the power semiconductor device package 100 with increased creepage distance(s), thereby reducing the adverse performance-related effects and increasing the current and voltage handling capabilities of the power semiconductor device package 100.

The creepage cutout 140 may have any suitable shape and/or configuration. By way of non-limiting example, the creepage cutout 140 may be a rectangular creepage cutout and/or a non-rectangular creepage cutout, such as a T-shaped creepage cutout. The creepage cutout 140 may have any suitable number of sidewall segments, such as at least two sidewall segments, such as at least six sidewall segments, such as at least eight sidewall segments, etc. The power semiconductor device package 100 may include other creepage extension features without deviating from the scope of the present disclosure.

The power semiconductor device package 100 may include a plurality of terminals 104. Each of the plurality of terminals 104 may be at least partly encapsulated by the housing 102 so that a portion of each of the plurality of terminals 104 is exposed. Each of the plurality of terminals 104 may be configured to be electrically coupled to an external device or component.

In some examples, the plurality of terminals 104 may include a first terminal 120, a second terminal 122, a third terminal 124, and a fourth terminal 126. The example should be understood to be non-limiting. The plurality of terminals 104, may include three terminals, five terminals, seven terminals, etc. In some examples, the plurality of terminals 104 may extend from the same side of the housing 102. For instance, the first terminal 120, the second terminal 122, the third terminal 124, and the fourth terminal 126 of the plurality of terminals 104 may extend in a generally parallel direction from the first minor side 102C of the housing 102.

In other examples, the plurality of terminals 104 extend from two or more sides of the housing 102.

The plurality of terminals may have the form of electrical connection pin structures or any other suitable structure. It should be understood that, although depicted as a plurality of pin connection structures, the plurality of terminals 104 may have any suitable form, such as extended leads, Gull-wing pins, contact pads, and/or the like.

Referring more specifically to FIGS. 2-4, the power semiconductor device package may include a submount 106. In some examples, the submount 106 may be and/or may include a lead frame, such as a conductive lead frame (e.g., copper lead frame) and/or the like. In some examples, the submount 106 may be and/or may include a power substrate, such as a direct bonded copper (DBC) substrate, an active metal brazed (AMB) substrate, and/or the like. In some examples, the submount 106 may be and/or may include a lead frame, and the lead frame may be arranged on a power substrate.

The power semiconductor device package 100 may have a first semiconductor die 108. The first semiconductor die 108 may be a silicon carbide-based semiconductor die. The power semiconductor package may have a second semiconductor die 110. The second semiconductor die 110 may be a silicon carbide-based semiconductor die. The first semiconductor die 108 and the second semiconductor die 110 may include one or more semiconductor devices, such as metal-oxide-semiconductor field-effect transistor (MOSFET) devices, Schottky diodes, and/or other devices. In some embodiments, the first semiconductor die 108 may be a MOSFET. In some embodiments, the second semiconductor die 110 may be a Schottky diode.

The first semiconductor die 108 (e.g., MOSFET) may be attached to the submount 106, for instance, using a die-attach material (not shown). In embodiments where the first semiconductor die 108 is a MOSFET, the first semiconductor die 108 may comprise a gate contact 112, a source contact 114, and a drain contact 142 (FIG. 4). The gate contact 112 may be electrically interconnected with a first electrical connector 116 with the fourth terminal 126. The first electrical connector 116 may be a clip, a wire bond, ribbon bond, etc. The source contact 114 may be electrically interconnected with a second electrical connector 118 with the second terminal 122. The second electrical connector 118 may be a clip, a wire bond, ribbon bond, etc. The drain contact 142 may be coupled to a first side 106A of the submount 106 (e.g., via a die-attach material). The submount 106 may be coupled to or integral with the first terminal 120 of the plurality of terminals 104.

Referring to FIG. 3, the second semiconductor die 110 may be coupled to a second side 106B of the submount 106 (e.g., via a die-attach material). The second side 106B of the submount 106 is opposite the first side 106A of the submount 106. In embodiments where the second semiconductor die 110 comprises a Schottky diode, the second semiconductor die comprises an anode contact 144 and a cathode contact 134. The cathode contact 134 may be coupled to the third terminal 124. The cathode contact 134 may be coupled to the third terminal 124 by a third electrical connector 128. The third electrical connector 128 may be a clip, a wire bond, ribbon bond, etc. The anode contact 144 may be coupled to the second side 106B of the submount 106 (e.g., via a die attach material). The submount 106 may be coupled to or integral with the first terminal 120 of a plurality of terminals 104.

As illustrated in FIG. 4, the first semiconductor die 108 and the second semiconductor die 110 may be coupled to opposing sides of the same submount 106. The first semiconductor die 108 may be coupled to the first side 106A of the submount 106 and the second semiconductor die 110 may be coupled to the second side 106B of the submount 106 (e.g., FIG. 4). The first side 106A of the submount 106 is opposite the second side 106B of the submount 106.

In some embodiments, where the first semiconductor die 108 is a MOSFET and the second semiconductor die 110 is a Schottky diode, the anode contact 144 of the Schottky diode may be coupled to the second side 106B of the submount 106. The second side 106B of the submount 106 may be coupled to or integral with the first terminal 120 of a plurality of terminals 104. The drain contact 142 of the MOSFET may be coupled to the first side 106A of the submount 106. The first side 106A of the submount 106 may be coupled to the first terminal 120 of a plurality of terminals 104. In this way, the drain contact 142 may be connected via the submount 106 to the same terminal 120 as the anode contact 144. As a result, as will be discussed in greater detail below, the semiconductor device package 100 may be used to implement power circuits (e.g., half bridge power circuits) where the first semiconductor die 108 and the second semiconductor die 110 are electrically coupled in a half-bridge configuration, where the drain contact 142 of the first semiconductor die 108 and the anode contact 142 of the second semiconductor die 110 are coupled to a common node.

In some examples, the first semiconductor die 108 may further include an additional contact, such as a source-Kelvin contact, a sensor contact, and/or the like. In some examples, the second semiconductor die 110 may further include an additional contact, such as a source-Kelvin contact, a sensor contact, and/or the like.

The semiconductor device package 100 may include a first electrical connector 130. The first electrical connector 130 may be a clip, a wire bond, ribbon bond, etc. The first electrical connector 130 may couple the first semiconductor die 108 to one of the plurality of terminals (e.g., the second terminal 122). The semiconductor device package 100 may include a second electrical connector 132. The second electrical connector 132 may be a clip, wire bond, ribbon bond, etc. The second electrical connector 132 may couple the second semiconductor die 110 to one of the plurality of terminals 104 (e.g., the third terminal 124).

In some embodiments, a portion of the first electrical connector 130 that is between the first semiconductor die 108 and the second terminal 122 may be exposed through the first major side 102A of the housing 102. In some embodiments, a portion of the second electrical connector 132 that is between the second semiconductor die 110 and the third terminal 124 may be exposed through the second major side 102B of the housing 102.

The exposed part of the first electrical connector 130 may be a thermally conductive structure. The thermally conductive structure may provide a heat dissipation path for the first semiconductor die 108 through the first major side 102A of the housing 102. The exposed part of the second electrical connector 132 may be a thermally conductive structure. The thermally conductive structure may provide a heat dissipation path for the second semiconductor die 110 through the second major side 102B of the housing 102.

In some examples, the exposed part of the first electrical connector 130 (e.g., as thermally conductive structure) may be coupled to an external heat sink (e.g., with an electrical isolator) to provide for cooling of the power semiconductor device package 100. Hence, the exposed part of the first electrical connector may provide for top-side cooling of the power semiconductor device package 100. In some examples, the exposed part of the second electrical connector 132 (e.g., as thermally conductive structure) may be coupled to an external heat sink (e.g., with an electrical isolator) to provide for cooling of the power semiconductor device package 100. Hence, the exposed part of the second electrical connector 132 may provide for bottom-side cooling of the power semiconductor device package 100.

Those having ordinary skill in the art, using the disclosures provided herein, will understand that the power semiconductor device packages described herein may include other power semiconductor devices without deviating from the scope of the present disclosure, such as diodes (e.g., Schottky diodes, PiN diodes, etc.), insulated gate bipolar transistors, high electron mobility transistors (HEMTs), and/or other devices. In addition, those having ordinary skill in the art, using the disclosures provided herein, will understand that the power semiconductor device packages described herein may have more than two semiconductor die. The power semiconductor device packages may include three, four, etc. semiconductor die.

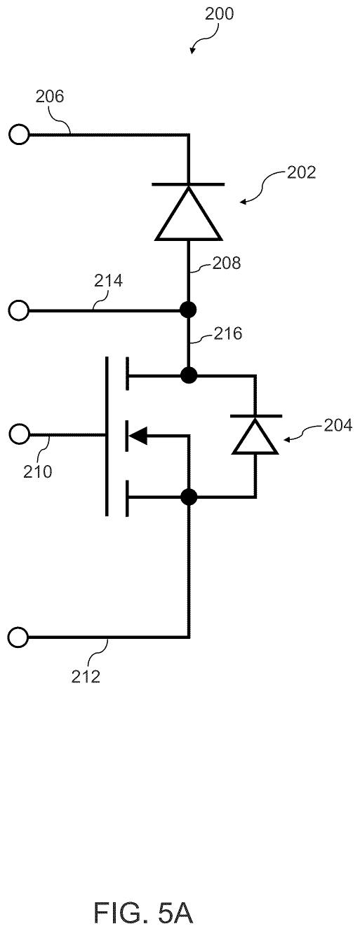

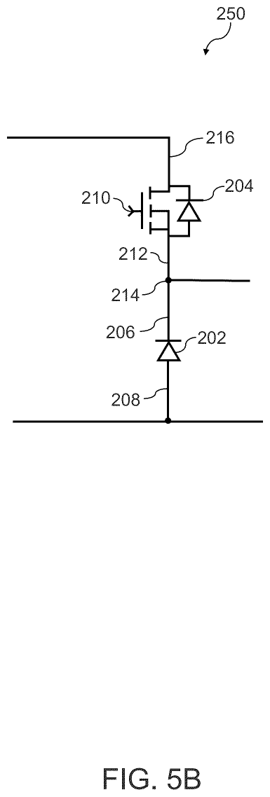

FIG. 5A depicts an example circuit diagram of example power circuit 200 that may be implemented by a power semiconductor device package according to example embodiments of the present disclosure, such as the power semiconductor device package 100 of FIGS. 1-4. The power circuit 200 may, in some example implementations, be a half-bridge circuit. The half-bridge circuit may include a Schottky diode 202, and a MOSFET 204. The Schottky diode 202 may have a cathode 206 and an anode 208. The MOSFET may have a drain 216, a gate 210, and a source 212. The Schottky diode 202 and the MOSFET 204 may be coupled at a common node 214. The common node 214 may be implemented by coupling the drain 216 of the MOSFET 204 and the anode 208 of the Schottky diode to the same submount, such as opposing sides of the same submount as depicted in FIG. 4.

Other suitable power circuits may be implemented using the semiconductor device package without deviating from the scope of the present disclosure. For instance, FIG. 5B illustrates a power circuit 250 that may be implemented at least in part in the semiconductor device packages according to examples of the present disclosure. The power circuit 250 may be part of, for instance, a buck converter. In the example of FIG. 5B the source 212 of the MOSFET 204 may be coupled to a first side of the submount. The cathode 206 of the Schottky diode 202 may be coupled to a second side of the submount. The first side of the submount may be an opposing side to the second side of the submount. In this way, the source 212 of the MOSFET 204 and the cathode 206 of the Schottky diode 202 may be coupled to a common node 214 (e.g., the submount).

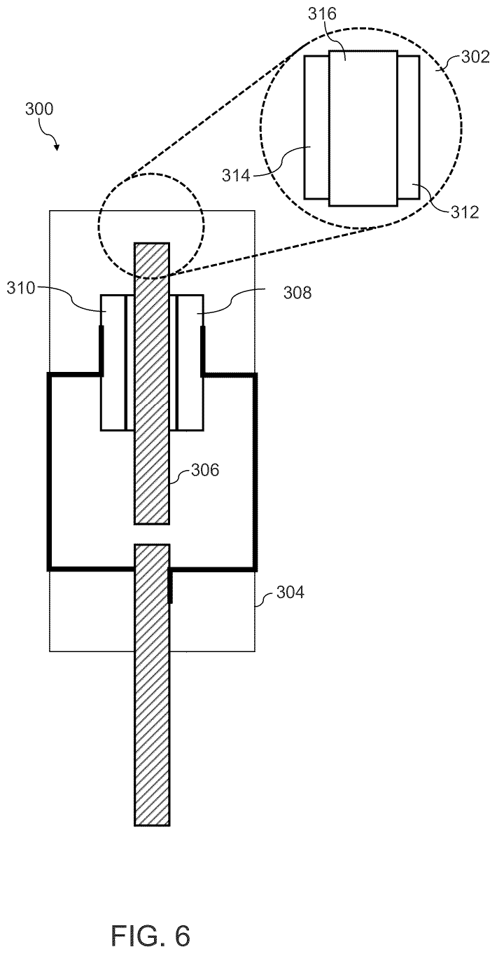

FIG. 6 depicts a cross-sectional view of a power semiconductor device package 300 that is similar to the power semiconductor device package 100 of FIGS. 1-4. The power semiconductor device package 300 may comprise a housing 304. The housing 304 may be formed by a mold press. In some examples, the housing 304 may be and/or may include an encapsulating material. By way of non-limiting example, the housing 304 may be and/or include an epoxy material, an epoxy mold compound, and/or the like.

The semiconductor device package 300 may include a submount, such as a power substrate 306. FIG. 6 provides a close-up view 302 of the power substrate 306. The power substrate 306 may be a direct bonded copper substrate, an active metal brazed substrate etc. The power substrate 306 may be coupled to a first semiconductor die 308 (e.g., a MOSFET) on a first side. The power substrate 306 may be coupled to a second semiconductor die 310 (e.g., a Schottky diode) on a second side opposite the first side.

The power substrate 306 may comprise a plurality of metal layers (e.g., 312, 314) and an insulating layer 316. The insulating layer 316 may be between the first metal layer 312 and the second metal layer 314. The insulating layer 316 may be formed from an insulating material, such as a ceramic material and/or other insulating materials. As such, the insulating layer 316 may provide electrical isolation between the first semiconductor die 308 and the second semiconductor die 310. In addition, in some examples, the insulating layer 316 may provide thermal isolation between the first semiconductor die 308 and the second semiconductor die 310. In some embodiments, the insulating layer 316 is thermally conductive and electrically insulating such that the first semiconductor die 308 and the second semiconductor die 310 are thermally coupled and electrically isolated.

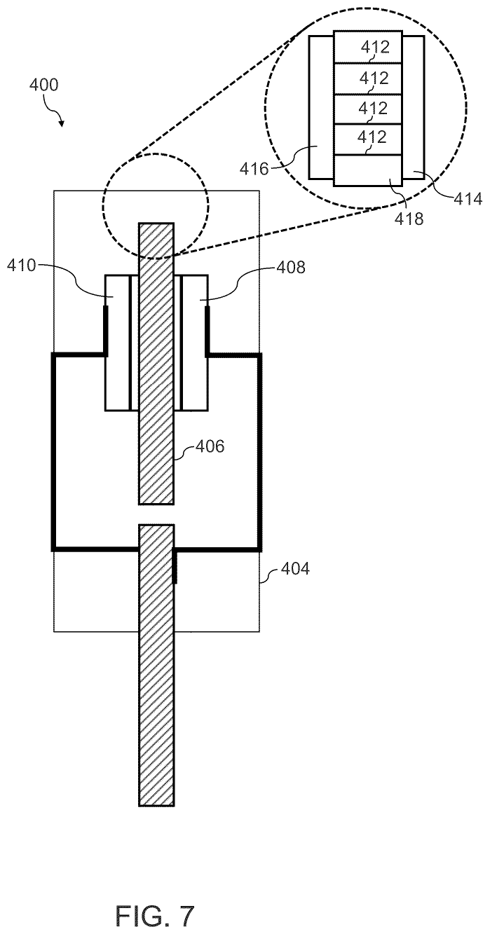

FIG. 7 depicts a cross-sectional view of a power semiconductor device package 400 that is similar to the power semiconductor device package 300 of FIG. 6. The power semiconductor device package 400 may comprise a housing 404. The housing 404 may be formed by a mold press. In some examples, the housing 404 may be and/or may include an encapsulating material. By way of non-limiting example, the housing 404 may be and/or may include an epoxy material, an epoxy mold compound, and/or the like.

The housing 404 may include a submount, such as a power substrate 406. FIG. 7 also depicts a close up view 402 of the power substrate 406. The power substrate 406 may be coupled to a first semiconductor die 408 (e.g., a MOSFET) on one side. The power substrate 406 may be coupled to a second semiconductor die 410 (e.g., a Schottky diode) on one side. The first semiconductor die 408 and the second semiconductor die 410 may be coupled on opposing sides of the power substrate.

The power substrate may comprise a plurality of metal layers (e.g., 414, 416) and an insulating layer 418. The insulating layer 418 may be in between the first metal layer 414 and the second metal layer 416. The insulating layer 418 may be formed from an insulating material, such as a ceramic material and/or other insulating materials. As such, the insulating layer 418 may provide thermal isolation between the first semiconductor die 408 and the second semiconductor die 410. The power substrate may include one or more vias 412. The vias 412 through the insulating layer 418 of the power substrate 406 may provide electrical connection between the first semiconductor die 408 (e.g., MOSFET) and the second semiconductor die 410 (e.g., Schottky diode) while still providing thermal isolation. It should be understood that there may be different arrangements of the power substrate 406 without deviating from the scope of the present disclosure. For example, the metal layers 414, 416 of the power substrate 406 may be electrically interconnected in other ways, such as through wire bonds or other interconnect structures connecting the metal layers 414, 416. As another example, the metal layers 414, 416 of the power substrate 406 may be electrically interconnected by through hole metallization and/or by a common electrical lead connected to both of the metal layers 414, 416.

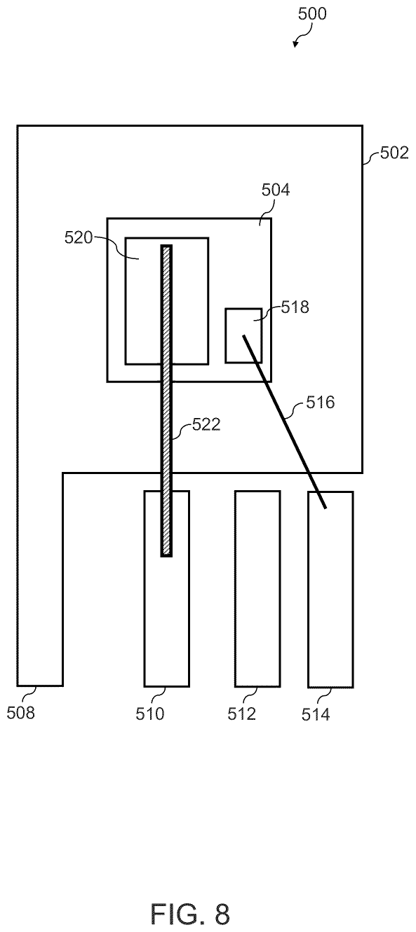

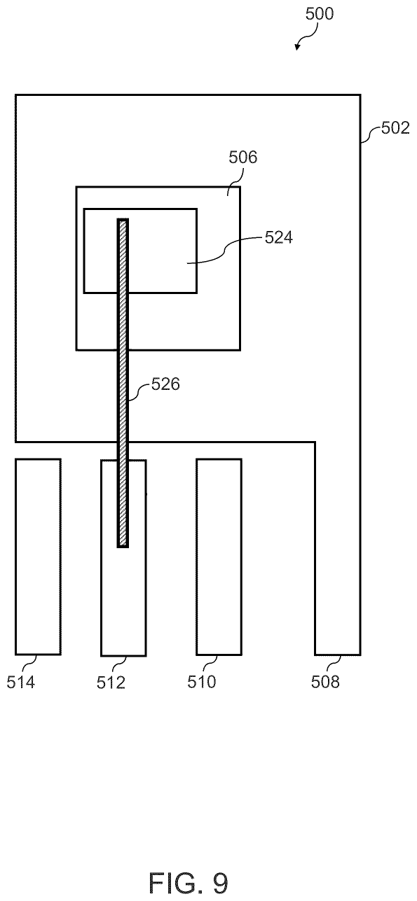

FIGS. 8 and 9 depict internal components of an example power semiconductor device package 500 that is similar to the power semiconductor device package 100 of FIGS. 1-4. FIGS. 8 and 9 depict a plan view of internal components of the power semiconductor device package 500.

The power semiconductor device package 500 includes a housing (e.g., 102, not currently shown). The housing may be formed by a mold press. The housing may include a material capable of high temperature operation, such as a temperature of about 200° C. or greater. In some examples, the housing may be and/or may include an encapsulating material. By way of non-limiting example, the housing may be and/or may include an epoxy material, an epoxy mold compound, and/or the like.

The power semiconductor device package 500 may include a plurality of terminals or leads. In some examples, the plurality of terminals may include a first terminal 508, a second terminal 510, a third terminal 512, and a fourth terminal 514. The example should be understood to be non-limiting. The plurality of terminals may have the form of electrical connection pin structures or any other suitable structure. It should be understood that, although depicted as a plurality of pin connection structures, the plurality of terminals may have any suitable form, such as extended leads, Gull-wing pins, contact pads, and/or the like.

The first semiconductor die 504 may be mounted on a submount 502. In some examples, the submount 502 may be and/or may include a power substrate, such as a direct bonded copper (DBC) substrate, an active metal brazed (AMB) substrate, and/or the like. In some examples, the submount 502 may be and/or may include a lead frame, such as a conductive lead frame (e.g., copper lead frame) and/or the like. In some examples, the submount 502 may be and/or may include a lead frame, and the lead frame may be arranged on a power substrate.

The power semiconductor device package 500 may have a first semiconductor die 504. The first semiconductor die 504 may be a silicon carbide-based semiconductor die. The power semiconductor package may have a second semiconductor die 506. The second semiconductor die 506 may be a silicon carbide-based semiconductor die. The first semiconductor die 504 and the second semiconductor die 506 may include one or more semiconductor devices, such as metal-oxide-semiconductor field-effect transistor (MOSFET) devices, Schottky diodes, and/or other devices. In some embodiments, the first semiconductor die 504 may be a MOSFET. In some embodiments, the second semiconductor die 506 may be a Schottky diode.

The first semiconductor die 504 (e.g., MOSFET) may be attached to a submount 502, for instance, using a die-attach material (not shown). In embodiments where the first semiconductor die 504 is a MOSFET, the first semiconductor die 504 may comprise a gate contact 518, a source contact 520, and a drain contact (not pictured). The gate contact 518 may be electrically interconnected with a first electrical connector 516 with the fourth terminal 514. The first electrical connector 522 as shown is a wire bond, but it should be understood that the first electrical connector 522 may be a clip, wire bond, ribbon bond, etc. The first electrical connector 522 may be exposed through the housing to provide a path for thermal dissipation.

Referring to FIG. 9, the second semiconductor die 506 (e.g., Schottky diode) may be attached to a submount 502, for instance, using a die-attach material (not shown). In embodiments where the second semiconductor die 506 comprises a Schottky diode, the second semiconductor die comprises an anode contact (not pictured) and a cathode contact 524. The cathode contact 524 may be coupled to the third terminal 512. The cathode contact 524 may be coupled to the third terminal 512 by a third electrical connector 526. The electrical connector 526 as pictured is a wire bond, but it should be understood that the third electrical connector 526 may be a clip, a wire bond, ribbon bond, etc. The third electrical connector 522 may be exposed through the housing to provide a path for thermal dissipation.

In some examples, the first semiconductor die 504 may further include an additional contact, such as a source-Kelvin contact, a sensor contact, and/or the like. In some examples, the second semiconductor die 506 may further include an additional contact, such as a source-Kelvin contact, a sensor contact, and/or the like.

Example aspects of the present disclosure are set forth below. Any of the below features or examples may be used in combination with any of the embodiments or features provided in the present disclosure.

One example aspect of the present disclosure is directed to a power semiconductor package. The power semiconductor package includes a first semiconductor die, a second semiconductor die, and a submount having a first side and a second side opposing the first side. The first semiconductor die is coupled to the first side of the submount, and the second semiconductor die is coupled to the second side of the submount.

In some examples, the first semiconductor die includes a metal-oxide-semiconductor field-effect transistor (MOSFET).

In some examples, the MOSFET includes a drain contact, a gate contact, and a source contact.

In some examples, the drain contact of the MOSFET is coupled to the submount.

In some examples, the source contact of the MOSFET is coupled to a submount.

In some examples, the power semiconductor package further includes a plurality of terminals.

In some examples, a first terminal of the plurality of terminals is coupled to the submount, a second terminal of the plurality of terminals is coupled to the source contact of the MOSFET, and a third terminal of the plurality of terminals is coupled to the gate contact.

In some examples, the source contact of the MOSFET is coupled to the second terminal with an electrical connector.

In some examples, at least a portion of the electrical connector is exposed through a housing of the power semiconductor package.

In some examples, the electrical connector includes a clip.

In some examples, the second semiconductor die includes a Schottky diode.

In some examples, the Schottky diode includes an anode contact and a cathode contact.

In some examples, the anode contact of the Schottky diode is coupled to the submount.

In some examples, the cathode contact of the Schottky diode is coupled to a terminal with an electrical connector.

In some examples, at least a portion of the electrical connector is exposed through a housing of the power semiconductor package.

In some examples, the first semiconductor die and the second semiconductor die are silicon carbide-based semiconductor die.

In some examples, the first semiconductor die and the second semiconductor die are electrically coupled in a half-bridge configuration in the power semiconductor package.

In some examples, the power semiconductor package further includes a housing.

In some examples, the housing includes an epoxy mold compound.

In some examples, the power semiconductor package further includes a first electrical connector coupled to the first semiconductor die, and a second electrical connector coupled to the second semiconductor die.

In some examples, at least a portion of the first electrical connector and at least a portion of the second electrical connector is exposed through the housing.

In some examples, the power semiconductor package has four terminals extending from same side of the housing.

In some examples, the submount is a lead frame.

In some examples, the submount is a power substrate.

In some examples, the power substrate is a direct bonded copper (DBC) or active metal brazed (AMB) substrate.

In some examples, the first semiconductor die and the second semiconductor die are thermally coupled.

In some examples, the first semiconductor die and the second semiconductor die are electrically coupled.

In some examples, the first semiconductor die and the second semiconductor die are electrically and thermally coupled.

In some examples, the first semiconductor die and the second semiconductor die are electrically coupled and thermally isolated.

In some examples, the first semiconductor die and the second semiconductor die are thermally coupled and electrically isolated.

In some examples, the first semiconductor die and the second semiconductor die are electrically and thermally isolated.

Another example aspect of the present disclosure is directed to a power semiconductor package. The power semiconductor package includes a first semiconductor die. The first semiconductor die includes a MOSFET. The power semiconductor package further includes a second semiconductor die. The second semiconductor die includes a Schottky diode. The power semiconductor package further includes a submount having a first side and a second side opposing the first side. The first semiconductor die is coupled to the first side of the submount, and the second semiconductor die is coupled to the second side of the submount.

In some examples, MOSFET includes a drain contact, a gate contact, and a source contact.

In some examples, the drain contact of the MOSFET is coupled to the first side of the submount.

In some examples, the source contact of the MOSFET is coupled to a submount.

In some examples, the power semiconductor package includes a plurality of terminals.

In some examples, a first terminal of the plurality of terminals is coupled to the drain contact of the MOSFET, a second terminal of the plurality of terminals is coupled to the source contact of the MOSFET, and a third terminal of a plurality of terminals is coupled to the gate contact.

In some examples, the source contact of the MOSFET is coupled to the second terminal with an electrical connector.

In some examples, at least a portion of the electrical connector is exposed through a housing of the power semiconductor package.

In some examples, the electrical connector includes a clip.

In some examples, the Schottky diode includes an anode contact and a cathode contact.

In some examples, wherein the anode contact of the Schottky diode is coupled to the submount.

In some examples, the cathode contact of the Schottky diode is coupled to an electrical connector.

In some examples, at least a portion of the electrical connector is exposed through a housing of the power semiconductor package.

In some examples, the first semiconductor die and the second semiconductor die are silicon carbide-based semiconductor die.

In some examples, the first semiconductor die and the second semiconductor die are electrically coupled in a half-bridge configuration in the power semiconductor package.

In some examples, the power semiconductor package includes a housing.

In some examples, the housing includes an epoxy mold compound.

In some examples, the power semiconductor package has four leads extending from same side of the housing.

In some examples, the power semiconductor package, further includes a first electrical connector coupled to first semiconductor die, and a second electrical connector coupled to the second semiconductor die.

In some examples, at least a portion of the first electrical connector and at least a portion of the second electrical connector is exposed through the housing.

In some examples, the submount is a lead frame.

In some examples, the submount is a power substrate.

In some examples, the power substrate is a direct bonded copper (DBC) or active metal brazed (AMB) substrate.

In some examples, the first semiconductor die and the second semiconductor die are thermally coupled.

In some examples, the first semiconductor die and the second semiconductor die are electrically coupled.

In some examples, the first semiconductor die and the second semiconductor die are electrically and thermally coupled.

In some examples, the first semiconductor die and the second semiconductor die are electrically coupled and thermally isolated.

In some examples, the first semiconductor die and the second semiconductor die are thermally coupled and electrically isolated.

In some examples, the first semiconductor die and the second semiconductor die are electrically and thermally isolated.

Another example aspect of the present disclosure is directed to a power semiconductor package. The power semiconductor package includes a first semiconductor die, a second semiconductor die, a first electrical connector coupled to the first semiconductor die and a first terminal of the power semiconductor package, a second electrical connector coupled to the second semiconductor die and a second terminal of the power semiconductor package, and a housing. At least a portion of the first electrical connector between the first semiconductor die and the first terminal is exposed through a first side of the housing, and at least a portion of the second electrical connector between the second semiconductor die and the second terminal is exposed through a second side of the housing. The first side of the housing is opposite the second side of the housing.

In some examples, the first semiconductor die includes a metal-oxide-semiconductor field-effect transistor (MOSFET).

In some examples, MOSFET includes a drain contact, a gate contact, and a source contact.

In some examples, the drain contact of the MOSFET is coupled to a submount.

In some examples, the source contact of the MOSFET is coupled to a submount.

In some examples, the power semiconductor package includes a plurality of terminals.

In some examples, a first terminal of the plurality of terminals is coupled to the drain contact of the MOSFET, a second terminal of the plurality of terminals is coupled to the source contact of the MOSFET, and a third terminal of the plurality of terminals is coupled to the gate contact.

In some examples, the second semiconductor die includes a Schottky diode.

In some examples, the Schottky diode includes an anode contact and a cathode contact.

In some examples, the anode contact of the Schottky diode is coupled to a submount.

In some examples, the cathode contact of the Schottky diode is coupled to a terminal with an electrical connector.

In some examples, the first semiconductor die and the second semiconductor die are silicon carbide-based semiconductor die.

In some examples, the first semiconductor die and the second semiconductor die are electrically coupled in a half-bridge configuration in the power semiconductor package.

In some examples, the housing includes an epoxy mold compound.

In some examples, the power semiconductor package has four terminals extending from same side of the housing.

In some examples, the power semiconductor package further includes a submount.

In some examples, the submount has a first side and a second side opposing the first side.

In some examples, the first semiconductor die is coupled to the first side of the submount, and the second semiconductor die is coupled to the second side of the submount.

In some examples, the submount is a lead frame.

In some examples, the submount is a power substrate.

In some examples, the power substrate is a direct bonded copper (DBC) or active metal brazed (AMB) substrate.

In some examples, the first electrical connector and the second electrical connector each include a clip.

In some examples, the first semiconductor die and the second semiconductor die are thermally coupled.

In some examples, wherein the first semiconductor die and the second semiconductor die are electrically coupled.

In some examples, the first semiconductor die and the second semiconductor die are electrically and thermally coupled.

In some examples, the first semiconductor die and the second semiconductor die are electrically coupled and thermally isolated.

In some examples, the first semiconductor die and the second semiconductor die are thermally coupled and electrically isolated.

In some examples, first semiconductor die and the second semiconductor die are electrically and thermally isolated.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor package, comprising:
a first semiconductor die;
a second semiconductor die; and
a submount having a first side and a second side opposing the first side;
wherein the first semiconductor die is coupled to the first side of the submount and the second semiconductor die is coupled to the second side of the submount.

2. The power semiconductor package of claim 1, wherein the first semiconductor die comprises a metal-oxide-semiconductor field-effect transistor (MOSFET).

3. The power semiconductor package of claim 2, wherein a drain contact of the MOSFET is coupled to the submount.

4. The power semiconductor package of claim 2, wherein a source contact of the MOSFET is coupled to the submount.

5. The power semiconductor package of claim 4, wherein:
a first terminal of a plurality of terminals is coupled to the submount;
a second terminal of the plurality of terminals is coupled to a source contact of the MOSFET; and
a third terminal of the plurality of terminals is coupled to a gate contact of the MOSFET.

6. The power semiconductor package of claim 5, wherein the source contact of the MOSFET is coupled to the second terminal with an electrical connector, wherein at least a portion of the electrical connector is exposed through a housing of the power semiconductor package.

7. The power semiconductor package of claim 1, wherein the second semiconductor die comprises a Schottky diode.

8. The power semiconductor package of claim 7, wherein an anode contact of the Schottky diode is coupled to the submount.

9. The power semiconductor package of claim 7, wherein a cathode contact of the Schottky diode is coupled to a terminal with an electrical connector, wherein at least a portion of the electrical connector is exposed through a housing of the power semiconductor package.

10. The power semiconductor package of claim 1, wherein the first semiconductor die and the second semiconductor die are silicon carbide-based semiconductor die.

11. The power semiconductor package of claim 1, wherein the first semiconductor die and the second semiconductor die are electrically coupled in a half-bridge configuration.

12. The power semiconductor package of claim 1, wherein the power semiconductor package comprises four terminals extending from a same side of a housing.

13. The power semiconductor package of claim 1, wherein the first semiconductor die and the second semiconductor die are thermally coupled.

14. The power semiconductor package of claim 1, wherein the first semiconductor die and the second semiconductor die are electrically coupled.

15. The power semiconductor package of claim 1, wherein the first semiconductor die and the second semiconductor die are electrically and thermally coupled.

16. The power semiconductor package of claim 1, wherein the first semiconductor die and the second semiconductor die are electrically coupled and thermally isolated.

17. The power semiconductor package of claim 1, wherein the first semiconductor die and the second semiconductor die are thermally coupled and electrically isolated.

18. The power semiconductor package of claim 1, wherein the first semiconductor die and the second semiconductor die are electrically and thermally isolated.

19. A power semiconductor package, comprising:
a first semiconductor die, wherein the first semiconductor die comprises a MOSFET;
a second semiconductor die, wherein the second semiconductor die comprises a Schottky diode; and
a submount having a first side and a second side opposing the first side;
wherein the first semiconductor die is coupled to the first side of the submount and the second semiconductor die is coupled to the second side of the submount.

20. A power semiconductor package, comprising:
a first semiconductor die;
a second semiconductor die;
a first electrical connector coupled to the first semiconductor die and a first terminal of the power semiconductor package;
a second electrical connector coupled to the second semiconductor die and a second terminal of the power semiconductor package;
a housing;
wherein at least a portion of the first electrical connector between the first semiconductor die and the first terminal is exposed through a first side of the housing; and
wherein at least a portion of the second electrical connector between the second semiconductor die and the second terminal is exposed through a second side of the housing;
wherein the first side of the housing is opposite the second side of the housing.
